(19) United States
(12) Patent Application Publication
(10) Pub. No.: US 2026/0334249 A1
(43) Pub. Date: Oct. 22, 2026

(54) SEMICONDUCTOR PACKAGE WITH POWER/GROUND WIRES CONNECTED TO CHIPS

(71) Applicant: SAMSUNG ELECTRONICS CO, LTD., Suwon-si (KR)

(72) Inventors: Hongjin KIM, Suwon-si (KR); Kihong JEONG, Suwon-si (KR)

(73) Assignee: SAMSUNG ELECTRONICS CO, LTD., Suwon-si (KR)

(21) Appl. No.: 19/384,242

(22) Filed: Nov. 10, 2025

(30) Foreign Application Priority Data
Apr. 16, 2025 (KR) 10-2025-0049403

(51) Int. Cl. H10W 70/60; H10W 90/00; H10W 72/00; H10W 72/50; H10W 90/24

(52) U.S. Cl. CPC H10W 70/60; H10W 70/611; H10W 90/00; H10W 72/07554; H10W 72/5473; H10W 72/884; H10W 90/24; H10W 90/701; H10W 90/732; H10W 90/734; H10W 90/752; H10W 90/754

(57) ABSTRACT

According to an aspect of the present disclosure, a semiconductor package includes a substrate including first bonding pads and second bonding pads, a first chip stack on the substrate, a second chip stack on the first chip stack, a third chip stack on the second chip stack, a fourth chip stack on the third chip stack, signal wires coupling the first bonding pads with signal pads of one or more first chips of the first chip stack, the second chip stack, the third chip stack, and the fourth chip stack, and power/ground wires coupling the second bonding pads with power/ground pads of one or more second chips of the first chip stack, the second chip stack, the third chip stack, and the fourth chip stack. The one or more first chips are different from the one or more second chips.

### CROSS-REFERENCE TO RELATED APPLICATIONS

This application claims priority under 35 U.S.C. § 119 to Korean Patent Application No. 10-2025-0049403, filed on April 16, 2025, in the Korean Intellectual Property Office, the disclosure of which is incorporated by reference herein in its entirety.

### BACKGROUND

### 1. Field

The present disclosure relates generally to semiconductor packages, and more particularly, to a semiconductor package having power/ground wires connected to a chip other than a chip to which signal wires are connected.

### 2. Description of Related Art

Recently, there may have been a demand for implementing relatively high performance and/or relatively high capacitance in semiconductor packages mounted on electronic devices. Accordingly, semiconductor packages having improved signal characteristics by including a plurality of semiconductor chips, which may be vertically stacked, may have been developed. For example, semiconductor packages handling high-frequency signals may be needed to be miniaturized and/or to have improved electrical characteristics.

### SUMMARY

One or more example embodiments of the present disclosure provide a semiconductor package having improved signal characteristics, when compared to related semiconductor packages.

According to an aspect of the present disclosure, a semiconductor package includes a substrate including first bonding pads and second bonding pads, a first chip stack on the substrate, a second chip stack on the first chip stack, a third chip stack on the second chip stack, a fourth chip stack on the third chip stack. The first bonding pads and the second bonding pads are disposed in a first direction. The first chip stack includes a plurality of first chips stacked vertically. The plurality of first chips include first signal pads and first power/ground pads. The first signal pads and the first power/ground pads are disposed in the first direction. The second chip stack includes a plurality of second chips stacked vertically. The plurality of second chips include second signal pads and second power/ground pads. The second signal pads and the second power/ground pads are disposed in the first direction. The third chip stack includes a plurality of third chips stacked vertically. The plurality of third chips include third signal pads and third power/ground pads. The third signal pads and the third power/ground pads are disposed in the first direction. The fourth chip stack includes a plurality of fourth chips stacked vertically. The plurality of fourth chips include fourth signal pads and fourth power/ground pads. The fourth signal pads and the fourth power/ground pads are disposed in the first direction. The semiconductor package further includes first signal wires coupling one or more of the first signal pads of a first chip of the plurality of first chips and the first bonding pads, second signal wires coupling one or more of the second signal pads of a first chip of the plurality of second chips and the first bonding pads, third signal wires coupling one or more of the third signal pads of a first chip of the plurality of third chips and the first bonding pads, fourth signal wires coupling the fourth signal pads of a first chip of the plurality of fourth chips and the first bonding pads, first power/ground wires coupling the first power/ground pads of a second chip of the plurality of first chips and the second bonding pads, second power/ground wires coupling the second power/ground pads of a second chip of the plurality of second chips and the second bonding pads, and third power/ground wires coupling the third power/ground pads of a second chip of the plurality of third chips and the second bonding pads. The second chip of the plurality of first chips is different from the first chip of the plurality of first chips. The second chip of the plurality of second chips is different from the first chip of the plurality of second chips. The second chip of the plurality of third chips is different from the first chip of the plurality of third chips.

According to an aspect of the present disclosure, a semiconductor package includes a substrate including first bonding pads and second bonding pads, a first chip stack including a plurality of first chips stacked on the substrate, a second chip stack including a plurality of second chips stacked on the first chip stack, first signal wires coupling one or more of the first signal pads of a first chip of the plurality of first chips and the first bonding pads, second signal wires coupling one or more of the second signal pads of a first chip of the plurality of second chips and the second bonding pads, and first power/ground wires coupling one or more first power/ground pads of a second chip of the plurality of first chips and the second bonding pads. The first bonding pads and the second bonding pads are disposed in a first direction. Each of the plurality of first chips include first signal pads and first power/ground pads. The first signal pads and the first power/ground pads are disposed in the first direction. Each of the plurality of second chips includes second signal pads and second power/ground pads. The second signal pads and the second power/ground pads are disposed in the first direction. The one or more first power/ground pads of the second chip are coupled with one or more of the second power/ground pads by first connection wires. The first signal pads of each of the plurality of first chips are coupled with the first signal wires by second connection wires. The second signal pads of each of the plurality of second chips are coupled with the second signal wires by third connection wires.

According to an aspect of the present disclosure, a semiconductor package includes a substrate including first bonding pads and second bonding pads, a plurality of semiconductor chips stacked on the substrate, each semiconductor chip of the plurality of semiconductor chips including signal pads and power/ground pads, and bonding wires coupling the first bonding pads and the second bonding pads to the plurality of semiconductor chips. The bonding wires include a first bonding wire coupling the first bonding pads to at least a portion of the signal pads of the plurality of semiconductor chips, and a second bonding wire coupling the second bonding pads to at least a portion of the power/ground pads of the plurality of semiconductor chips. A second chip of the plurality of semiconductor chips to which the second bonding wire is coupled is stacked above or below a first chip of the plurality of semiconductor chips to which the first bonding wire is coupled.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a perspective view of a semiconductor package, according to an example embodiment;

FIG. 2 is a schematic plan view of a semiconductor package, according to an example embodiment;

FIG. 3A is a schematic cross-sectional view of a semiconductor package,

according to an example embodiment;

FIG. 3B is a schematic cross-sectional view of a semiconductor package, according to example embodiments;

FIG. 3C is a schematic cross-sectional view of a semiconductor package, according to example embodiments;

FIG. 4A is a schematic cross-sectional view of a semiconductor package, according to example embodiments;

FIG. 4B is a schematic cross-sectional view of a semiconductor package, according to example embodiments;

FIG. 4C is a schematic cross-sectional view of a semiconductor package, according to example embodiments;

FIG. 4D is a schematic cross-sectional view of a semiconductor package, according to example embodiments;

FIG. 5 is a schematic plan view of a semiconductor package, according to an example embodiment;

FIG. 6A is a schematic cross-sectional view of a semiconductor package, according to example embodiment;

FIG. 6B is a schematic cross-sectional view of a semiconductor package, according to example embodiments;

FIG. 7 is a schematic plan view of a semiconductor package, according to an example embodiment;

FIG. 8A is a schematic cross-sectional view of a semiconductor package,

according to example embodiment;

FIG. 8B is a schematic cross-sectional view of a semiconductor package, according to example embodiments;

FIG. 9 is a schematic plan view of a semiconductor package, according to an example embodiment;

FIG. 10A is a schematic cross-sectional view of a semiconductor package, according to example embodiment;

FIG. 10B is a schematic cross-sectional view of a semiconductor package, according to example embodiments;

FIG. 11 is a schematic plan view of a semiconductor package, according to an example embodiment;

FIG. 12A is a schematic cross-sectional view of a semiconductor package, according to example embodiment;

FIG. 12B is a schematic cross-sectional view of a semiconductor package, according to example embodiments;

FIG. 13 is a schematic plan view of a semiconductor package, according to an example embodiment;

FIG. 14A is a schematic cross-sectional view of a semiconductor package, according to example embodiment; and

FIG. 14B is a schematic cross-sectional view of a semiconductor package, according to example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

Unless otherwise specifically stated, as used herein, terms such as, but not limited to, “upper,” “top surface,” “lower surface,” “lower surface,” and “side surface” are based on the drawings, and may actually vary depending on the direction in which the components are disposed.

In addition, ordinal numbers such as, but not limited to, “first,” “second,” “third,” or the like may be used as labels for specific elements, steps, directions, or the like to distinguish between various elements, steps, directions, or the like. Terms not described in the present disclosure using “first,” “second,” or the like may still be referred to as “first” or “second” in the claims. In addition, terms referenced by a particular ordinal number (e.g., “first” in a particular claim) may be described elsewhere by a different ordinal number (e.g., “second” in the specification or in another claim).

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a chip” may refer to either a single chip or multiple chips. When a chip is described as carrying out an operation and the chip is referred to perform an additional operation, the multiple operations may be executed by either a single chip or any one or a combination of multiple chips.

Hereinafter, various embodiments of the present disclosure are described with reference to the accompanying drawings.

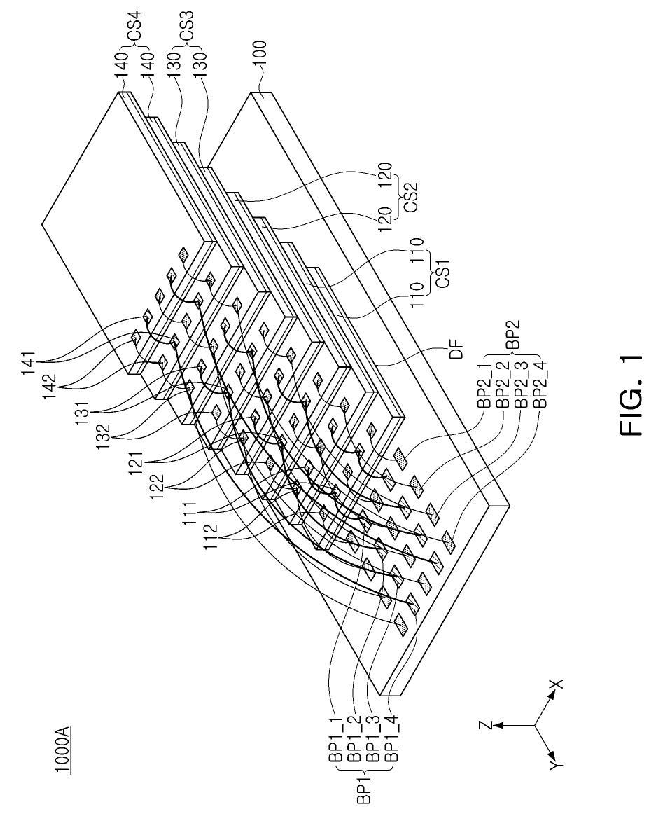

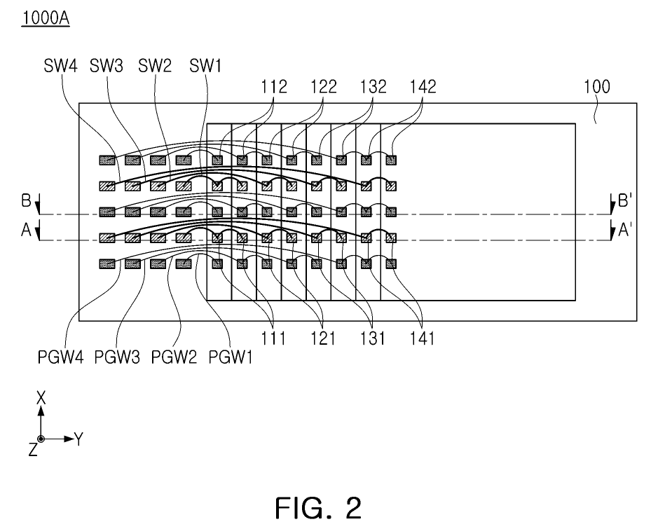

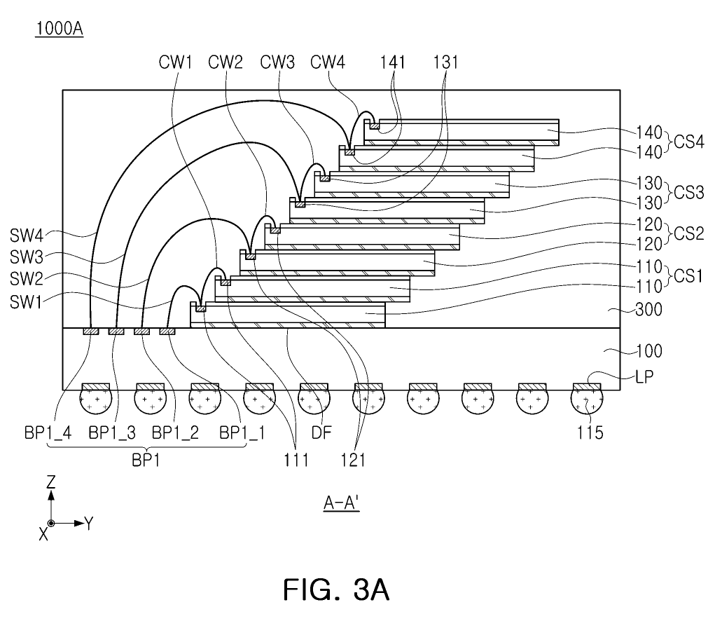

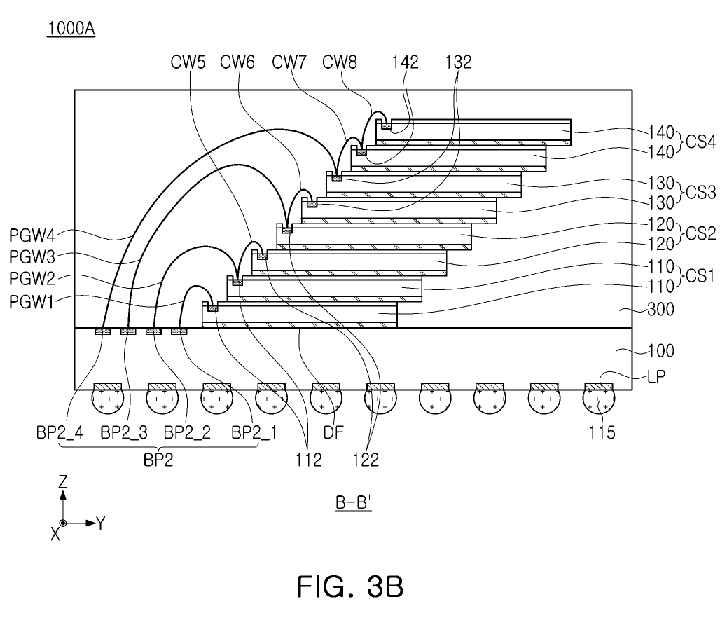

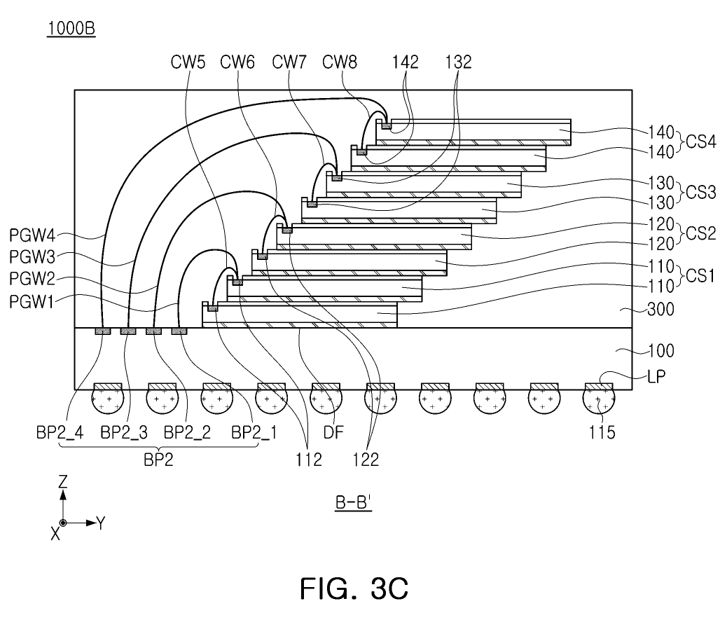

FIG. 1 is a perspective view of a semiconductor package 1000A, according to an example embodiment. FIG. 2 is a schematic plan view of a semiconductor package 1000A, according to an example embodiment. FIG. 3A is a schematic cross-sectional view of a semiconductor package 1000A, according to an example embodiment. FIG. 3A illustrates a cross-section of FIG. 2, taken along the cutting line A–A'. FIG. 3B is a schematic cross-sectional view of a semiconductor package 1000A, according to an example embodiment. FIG. 3B illustrates a cross-section of FIG. 2, taken along the cutting line B–B'.

Referring to FIGS. 1, 2, 3A, and 3B, the semiconductor package 1000A, according to an example embodiment, may include a substrate 100, a plurality of chip stacks (e.g., a first chip stack CS1, a second chip stack CS2, a third chip stack CS3, and a fourth chip stack CS4), a plurality of signal wires (e.g., a first signal wire SW1, a second signal wire SW2, a third signal wire SW3, and a fourth signal wire SW4), a plurality of power/ground wires (e.g., a first power/ground wire PGW1, a second power/ground wire PGW2, a third power/ground wire PGW3, and a fourth power/ground wire PGW4), a plurality of connection wires (e.g., a first connection wire CW1, a second connection wire CW2, a third connection wire CW3, and a fourth connection wire CW4, a fifth connection wire CW5, a sixth connection wire CW6, a seventh connection wire CW7, and an eighth connection wire CW8), and an encapsulant 300.

Hereinafter, each component of the semiconductor package 1000A is described.

The substrate 100 may be and/or may include a semiconductor package substrate including a printed circuit board (PCB), a ceramic substrate, a glass substrate, a tape wiring board, or the like. For example, the substrate 100 may be and/or may include a double-sided PCB and/or a multi-layer PCB. The substrate 100 may include first bonding pads BP1, second bonding pads BP2, and lower pads LP.

The first bonding pads BP1 and the second bonding pads BP2 may be disposed on an upper surface of the substrate 100. The lower pads LP may be disposed on a lower surface of the substrate 100. The first and second bonding pads BP1 and BP2 may be electrically connected to the lower pads LP through an internal circuit. The first bonding pads BP1, the second bonding pads BP2, and the lower pads LP may include at least one metal or an alloy of two (2) or more metals such as, but not limited to, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C).

Connection bumps 115 may be disposed below the lower pads LP. The connection bumps 115 may be formed of a conductive material having a shape such as, but not limited to, a ball, a pin, or the like. The connection bumps 115 may include, for example, tin (Sn) or an alloy including tin (Sn) (e.g., tin-silver-copper (Sn-Ag-Cu)). The connection bumps 115 may be electrically connected to an external device such as, but not limited to, a module substrate a system board, or the like.

The substrate 100 may include first and second bonding pads BP1 and BP2 disposed in a first direction (e.g., an X-direction). The first bonding pads BP1 may be and/or may include, for example, signal pads connected to input and/or output terminals of data signals. The second bonding pads BP2 may be and/or may include, for example, power and/or ground pads connected to power terminals and/or ground terminals. The first bonding pads BP1 and the second bonding pads BP2 may be spaced apart from each other in the first direction (e.g., the X-direction) and may be electrically isolated.

The first bonding pads BP1 may include a plurality of first bonding pads (e.g., 1_1 bonding pads BP1_1, 1_2 bonding pads BP1_2, 1_3 bonding pads BP1_3, and 1_4 bonding pads BP1_4) spaced apart from each other in a second direction (e.g., a Y-direction), intersecting the first direction (e.g., the X-direction). The plurality of first bonding pads BP1_1 to BP1_4 may be sequentially disposed adjacently to a chip stack (e.g., the first chip stack CS1). For example, the 1_1 bonding pads BP1_1 may be disposed more adjacently to the first chip stack CS1 than the 1_2 bonding pads BP1_2, the 1_2 bonding pads BP1_2 may be disposed more adjacently to the first chip stack CS1 than the 1_3 bonding pads BP1_3, and the 1_3 bonding pads BP1_3 may be disposed more adjacently to the first chip stack CS1 than the 1_4 bonding pads BP1_4.

The second bonding pads BP2 may include a plurality of second bonding pads (e.g., 2_1 bonding pads BP2_1, 2_2 bonding pads BP2_2, 2_3 bonding pads BP2_3, and 2_4 bonding pads BP2_4) spaced apart from each other in a second direction (e.g., a Y-direction), intersecting the first direction (e.g., the X-direction). The plurality of second bonding pads BP2_1 to BP2_4 may be sequentially disposed adjacently to a chip stack (e.g., the first chip stack CS1). For example, the 2_1 bonding pads BP2_1 may be disposed more adjacently to the first chip stack CS1 than the 2_2 bonding pads BP2_2, the 2_2 bonding pads BP2_2 may be disposed more adjacently to the first chip stack CS1 than the 2_3 bonding pads BP2_3, and the 2_3 bonding pads BP2_3 may be disposed more adjacently to the first chip stack CS1 than the 2_4 bonding pads BP2_4. A distance at which the plurality of first bonding pads BP1_1 to BP1_4 are spaced from each other may be substantially similar and/or the same as a distance at which the plurality of second bonding pads BP2_1 to BP2_4 are spaced from each other.

Although FIGS. 1, 2, 3A, and 3B illustrate the first bonding pads BP1 as being arranged twice (e.g., two (2) times) in a first direction (e.g., X direction) between the second bonding pads BP2, and that the second bonding pads BP2 as being arranged three (3) times in the first direction (e.g., X direction), embodiments of the present disclosure are not limited thereto and may vary depending on the example embodiment.

A plurality of semiconductor chips (e.g., a plurality of first chips 110, a plurality of second chips 120, a plurality of third chips 130, and a plurality of fourth chips) 140 may be and/or may include, for example, non-volatile memory semiconductor chips such as, but not limited to, flash memory, phase-change random access memory (PRAM), magnetoresistive random access memory (MRAM), ferroelectric random access memory (FeRAM), resistive random access memory (RRAM), or the like, and/or volatile memory semiconductor chips such as, but not limited to, dynamic random access memory (DRAM), static random access memory (SRAM), or the like. The plurality of semiconductor chips 110 to 140 may include the same type of semiconductor chip. However, embodiments of the present disclosure are not limited thereto. According to an example embodiment, the plurality of semiconductor chips 110 to 140 may include different types of semiconductor chips.

The plurality of semiconductor chips 110 to 140 may be stacked in a vertical direction (e.g., Z-direction) on the substrate 100. The plurality of semiconductor chips 110 to 140 may be attached to and/or mutually attached to the substrate 100 by an adhesive film DF. The adhesive film DF may be formed using an adhesive film, an adhesive paste, or the like. The adhesive film DF may be a Die Attach Film (DAF). However, embodiments of the present disclosure are not limited thereto.

The plurality of semiconductor chips 110 to 140 may form the plurality of chip stacks CS1 to CS4. As used herein, a chip stack may refer to a plurality of chips transmitting and receiving data through a single channel. Although FIGS. 1, 2, 3A, and 3B illustrate the plurality of semiconductor chips 110 to 140 as having eight (8) semiconductor chips, embodiments of the present disclosure are not limited thereto. For example, the plurality of semiconductor chips 110 to 140 may include fewer chips (e.g., less than eight (8)) or more chips (e.g., greater than eight (8)). In addition, the number of semiconductor chips forming one chip stack (e.g., the first chip stack CS1, the second chip stack CS2, the third chip stack CS3, or the fourth chip stack CS4) may be less than or greater than the number of semiconductor chips shown in FIGS. 1, 2, 3A, and 3B (e.g., two (2)). That is, the number of semiconductor chips forming one chip stack may be greater than two (2). For example, the number of semiconductor chips forming one chip stack may be four (4), six (6), nine (9), sixteen (16), or the like. Alternatively or additionally, the number of semiconductor chips in one or more chip stacks of the plurality of chip stacks CS1 to CS4 may be different from the number of semiconductor chips in the remaining chip stacks of the plurality of chip stacks CS1 to CS4.

Each of the plurality of semiconductor chips 110 to 140 may transmit output signals and/or receive input signals through different channels. For example, the semiconductor package 1000A, according to an example embodiment, may include four (4) channels, as illustrated in FIGS. 1, 2, 3A, and 3B. However, embodiments of the present disclosure are not limited thereto.

The semiconductor package 1000A, according to an example embodiment, may include the first chip stack CS1 on the substrate 100, the second chip stack CS2 on the first chip stack CS1, the third chip stack CS3 on the second chip stack CS2, and the fourth chip stack CS4 on the third chip stack CS3.

The first chip stack CS1 may include the plurality of first chips 110 including first signal pads 111 and first power/ground pads 112, alternately arranged with each other in a first direction (e.g., X-direction) stacked thereon. The second chip stack CS2 may include the plurality of second chips 120 including second signal pads 121 and second power/ground pads 122, alternately arranged with each other in the first direction (e.g., X-direction) stacked thereon. The third chip stack CS3 may include the plurality of third chips 130 including third signal pads 131 and third power/ground pads 132, alternately arranged with each other in the first direction (e.g., X-direction) stacked thereon. The fourth chip stack CS4 may include the plurality of fourth chips 140 including fourth signal pads 141 and fourth power/ground pads 142, alternately arranged with each other in the first direction (e.g., X-direction) stacked thereon.

The plurality of semiconductor chips 110 to 140 may be stacked to be offset in one direction (e.g., Y-direction) so that each of the first to fourth signal pads 111 to 141 and each of the first to fourth power/ground pads 112 to 142 are exposed in a vertical direction (e.g., Z-direction).

The plurality of signal pads 111 to 141 and the plurality of power/ground pads 112 to 142 may include, for example, at least one of copper (Cu), nickel (Ni), titanium (Ti), aluminum (Al), or alloys thereof. The plurality of signal pads signal pads 111 to 141 may be and/or may include signal pads for inputting and/or outputting data signals, and the plurality of power/ground pads 112 to 142 may be and/or may include power pads for supplying power and/or ground voltages.

According to example embodiments, the plurality of semiconductor chips 110 to 140 may arrange signal pads and power/ground pads alternately in a first direction (e.g., X-direction) and may connect long wires to the power/ground pads, thereby reducing a return path in an environment in which a high-frequency signal may be transmitted in the form of a field. Accordingly, signal integrity (SI) characteristics may be improved, when compared to related semiconductor packages, by lowering inductance and minimizing voltage fluctuations.

The plurality of first to eighth connection wires CW1 to CW8 may electrically connect the plurality of semiconductor chips 110 to 140 to each other. The plurality of first to eighth connection wires CW1 to CW8 may include, for example, gold (Au), silver (Ag), lead (Pb), aluminum (Al), copper (Cu) or alloys thereof. However, embodiments of the present disclosure are not limited thereto.

The first connection wires CW1 may electrically connect the plurality of first chips 110 to each other. Accordingly, the first signal pads 111 of the plurality of first chips 110 may be connected to each other by the first connection wires CW1. The second connection wires CW2 may electrically connect the plurality of second chips 120 to each other. Accordingly, the second signal pads 121 of the plurality of second chips 120 may be connected to each other by the second connection wires CW2. The third connection wires CW3 may electrically connect the plurality of third chips 130 to each other. Accordingly, the third signal pads 131 of the plurality of third chips 130 may be connected to each other by the third connection wires CW3. The fourth connection wires CW4 may electrically connect the plurality of fourth chips 140 to each other. Accordingly, the fourth signal pads 141 of the plurality of fourth chips 140 may be connected to each other by the fourth connection wires CW4.

In addition, the first signal pads 111 of each of the plurality of first chips 110 may be electrically connected to the first signal wires SW1 by the first connection wires CW1. The second signal pads 121 of each of the plurality of second chips 120 may be electrically connected to the second signal wires SW2 by the second connection wires CW2. The third signal pads 131 of each of the plurality of third chips 130 may be electrically connected to the third signal wires SW3 by the third connection wires CW3. The fourth signal pads 141 of each of the plurality of fourth chips 140 may be electrically connected to the fourth signal wires SW4 by the fourth connection wires CW4.

The first signal pads 111 of the plurality of first chips 110 may be electrically isolated from the second signal pads 121 of the plurality of second chips 120. The second signal pads 121 of the plurality of second chips 120 may be electrically isolated from the third signal pads 131 of the plurality of third chips 130. The third signal pads 131 of the plurality of third chips 130 may be electrically isolated from the fourth signal pads 141 of the plurality of fourth chips.

The fifth connection wires CW5 may electrically connect the plurality of first chips 110 and the plurality of second chips 120 to each other. Accordingly, the first power/ground pads 112 of an uppermost chip of the plurality of first chips 110 and the second power/ground pads 122 of a lowermost chip of the plurality of second chips 120 may be connected to each other by the fifth connection wires CW5. The sixth connection wires CW6 may electrically connect the plurality of second chips 120 and the plurality of third chips 130 to each other. Accordingly, the second power/ground pads 122 of an uppermost chip of the plurality of second chips 120 and the third power/ground pads 132 of a lowermost chip of the plurality of third chips 130 may be connected to each other by the sixth connection wires CW6. The seventh connection wires CW7 may electrically connect the plurality of third chips 130 and the plurality of third chips 130 to each other. Accordingly, the third power/ground pads 132 of an uppermost chip of the plurality of third chips 130 and the fourth power/ground pads 142 of a lowermost chip of the plurality of fourth chips 140 may be connected to each other by the seventh connection wires CW7. The eighth connection wires CW8 may electrically connect the plurality of fourth chips 140 to each other. Accordingly, the fourth power/ground pads 142 of the plurality of fourth chips 140 may be connected to each other by the eighth connection wires CW8.

The third power/ground pads 132 of a chip to which the fourth power/ground wires PGW4 are connected and the fourth power/ground pads 142 of the plurality of fourth chips 140 on a chip to which the fourth power/ground wires PGW4 are connected may be electrically connected to each other by the seventh and eighth connection wires CW7 and CW8. The second power/ground pads 122 of a chip to which the third power/ground wires PGW3 are connected and the third power/ground pads 132 of the plurality of third chips 130 on a chip to which the third power/ground wires PGW3 are connected may be electrically connected to each other by the sixth wires CW6. The first power/ground pads 112 of a chip to which the second power/ground wires PGW2 are connected and the second power/ground pads 122 of the plurality of second chips 120 on a chip to which the second power/ground wires PGW2 are connected may be electrically connected to each other by the fifth wires CW5.

The third power/ground pads 132 of a chip to which the fourth power/ground wires PGW4 are connected and the third power/ground pads 132 of the plurality of third chips 130 stacked below the chip to which the fourth power/ground wires PGW4 are connected may be electrically isolated. The second power/ground pads 122 of a chip to which the third power/ground wires PGW3 are connected and the second power/ground pads 122 of the plurality of second chips 120 stacked below the chip to which the third power/ground wires PGW3 are connected may be electrically isolated. The first power/ground pads 112 of a chip to which the second power/ground wires PGW2 are connected and the first power/ground pads 112 of the plurality of first chips 110 stacked below the chip to which the second power/ground wires PGW2 are connected may be electrically isolated.

The first signal wires SW1 may electrically connect the first signal pads 111 of any one of the plurality of first chips 110 and 1_1 bonding pads BP1_1 of the substrate 100. For example, the first signal wires SW1 may electrically connect the first signal pads 111 of a lowermost chip of the plurality of first chips 110 and the 1_1 bonding pads BP1_1 of the substrate 100. The second signal wires SW2 may electrically connect the second signal pads 121 of any one of the plurality of second chips 120 and 1_2 bonding pads BP1_2 of the substrate 100. For example, the second signal wires SW2 may electrically connect the second signal pads 121 of a lowermost chip of the plurality of second chips 120 and the 1_2 bonding pads BP1_2 of the substrate 100. The third signal wires SW3 may electrically connect the third signal pads 131 of any one of the plurality of third chips 130 and 1_3 bonding pads BP1_3 of the substrate 100. For example, the third signal wires SW3 may electrically connect the third signal pads 131 of a lowermost chip of the plurality of third chips 130 and the 1_3 bonding pads BP1_3 of the substrate 100. The fourth signal wires SW4 may electrically connect the fourth signal pads 141 of any one of the plurality of fourth chips 140 and 1_4 bonding pads BP1_4 of the substrate 100. For example, the fourth signal wires SW4 may electrically connect the fourth signal pads 141 of a lowermost chip of the plurality of fourth chips 140 and the 1_4 bonding pads BP1_4 of the substrate 100.

The first to fourth power/ground wires PGW1 to PGW4 may be respectively connected to first to fourth power/ground pads 112 to 142 of a chip other than a semiconductor chip to which the first to fourth signal wires SW1 to SW4 are connected. For example, the second to fourth power/ground wires PGW2 to PGW4 may be respectively connected to power/ground pads of a semiconductor chip stacked below a chip to which the second to fourth signal wires SW2 to SW4 are connected. The second power/ground wires PGW2 may electrically connect the first power/ground pads 112 of an uppermost chip of the plurality of first chips 110 and the 2_2 bonding pads BP2_2 of the substrate 100. The third power/ground wires PGW3 may electrically connect the second power/ground pads 122 of an uppermost chip of the plurality of second chips 120 and the 2_3 bonding pads BP2_3 of the substrate 100. The fourth power/ground wires PGW4 may electrically connect the third power/ground pads 132 of an uppermost chip of the plurality of third chips 130 and the 2_4 bonding pads BP2_4 of the substrate 100. Similar to the connection method of the first signal wires SW1, the first power/ground wires PGW1 may electrically connect the first power/ground pads 112 of the lowermost chip of the plurality of first chips 110 and the 2_1 bonding pads BP2_1 of the substrate 100.

According to an example embodiment, the first to fourth power/ground wires PGW1 to PGW4 may be respectively connected to first to fourth power/ground pads 112 to 142 of a chip other than a semiconductor chip to which the first to fourth signal wires SW1 to SW4 are connected, thereby securing a spaced gap between the power/ground wires and the signal wires. Accordingly, the risk of shorts occurring between adjacent wires may be reduced, and a semiconductor package having improved reliability may be provided, when compared to related semiconductor packages.

According to an example embodiment, the second to fourth signal wires SW2 to SW4 may have different lengths from the second to fourth power/ground wires PGW2 to PGW4, respectively. Accordingly, the second to fourth signal wires SW2 to SW4 may overlap each of the second to fourth power/ground wires PGW2 to PGW4 at least in the first direction (e.g., X-direction) to secure a spaced gap between the power/ground wires and the signal wire, and to reduce the risk of a short occurring between adjacent wires.

The encapsulant 300 may cover the plurality of first to fourth chip stacks CS1 to CS4, the plurality of first to fourth signal wires SW1 to SW4, the plurality of first to fourth power/ground wires PGW1 to PGW4, and the plurality of first to eighth connection wires CW1 to CW8 on the substrate 100. The encapsulant 300 may include, but not be limited to, a thermosetting resin such as an epoxy resin, a thermoplastic resin such as a polyimide, and/or a resin impregnated with an inorganic filler, for example, prepreg, Ajinomoto build-up film (ABF), FR-4, bismaleimide triazine (BT), or epoxy molding compound (EMC).

FIG. 3C is a schematic cross-sectional view of a semiconductor package 1000B, according to an example embodiment. FIG. 3C illustrates a cross-section taken along line B–B' of FIG. 2 and illustrates a diagram, corresponding to FIG. 3B.

A semiconductor package 1000B of FIG. 3C may include and/or may be similar in many respects to the semiconductor package 1000A described above with reference to FIGS. 1, 2, 3A, and 3B, and may include additional features not mentioned above. For example, a dispositional state of first to fourth power/ground wires PGW1 to PGW4 of the semiconductor package 1000B may differ. Consequently, repeated descriptions of the semiconductor package 1000B described above with reference to FIGS. 1, 2, 3A, and 3B, may be omitted for the sake of brevity.

Referring to FIG. 3C, in an example embodiment, the fifth connection wires CW5 may electrically connect the plurality of first chips 110 to each other. Accordingly, the first power/ground pads 112 of the plurality of first chips 110 may be connected to each other by the fifth connection wires CW5. The sixth connection wires CW6 may electrically connect the plurality of second chips 120 to each other. Accordingly, the second power/ground pads 122 of the plurality of second chips 120 may be connected to each other by the sixth connection wires CW6. The seventh connection wires CW7 may electrically connect the plurality of third chips 130 to each other. Accordingly, the third power/ground pads 132 of the plurality of third chips 130 may be connected to each other by the sixth connection wires CW7. The eighth connection wires CW8 may electrically connect the plurality of fourth chips 140 to each other. Accordingly, the fourth power/ground pads 142 of the plurality of fourth chips 140 may be connected to each other by the eighth connection wires CW8.

In addition, the first power/ground pads 112 of each of the plurality of first chips 110 may be electrically connected to the first power/ground wires PGW1 by the fifth connection wires CW5. The second power/ground pads 122 of each of the plurality of second chips 120 may be electrically connected to the second power/ground wires PGW2 by the sixth connection wires CW6. In addition, the third power/ground pads 132 of each of the plurality of third chips 130 may be electrically connected to the third power/ground wires PGW3 by the seventh connection wires CW7. The fourth power/ground pads 142 of each of the plurality of fourth chips 140 may be electrically connected to the fourth power/ground wires PGW4 by the eighth connection wires CW8.

The first power/ground pads 112 of the plurality of first chips 110 and the second power/ground pads 122 of the plurality of second chips 120 may be electrically isolated. The second power/ground pads 122 of the plurality of second chips 120 and the third power/ground pads 132 of the plurality of third chips 130 may be electrically isolated. The third power/ground pads 132 of the plurality of third chips 130 and the fourth power/ground pads 142 of the plurality of fourth chips 140 may be electrically isolated.

In an example embodiment, the first to fourth power/ground wires PGW1 to PGW4 may be respectively connected to first to fourth power/ground pads 112 to 142 of a chip other than the semiconductor chip to which the first to fourth signal wires SW1 to SW4 are connected. For example, the first to fourth power/ground wires PGW1 to PGW4 may be respectively connected to power/ground pads of a chip other than the semiconductor chip stacked above the chip to which the first to fourth signal wires SW1 to SW4 are connected. The first power/ground wires PGW1 may electrically connect the first power/ground pads 112 of an uppermost chip of the plurality of first chips 110 and the 2_1 bonding pads BP2_1 of the substrate 100. The second power/ground wires PGW2 may electrically connect the second power/ground pads 122 of an uppermost chip of the plurality of second chips 120 and the 2_2 bonding pads BP2_2 of the substrate 100. The third power/ground wires PGW3 may electrically connect the third power/ground pads 132 of an uppermost chip of the plurality of third chips 130 and the 2_3 bonding pads BP2_4 of the substrate 100. The fourth power/ground wires PGW4 may electrically connect the second power/ground pads 122 of an uppermost chip of the plurality of fourth chips 140 and the 2_4 bonding pads BP2_4 of the substrate 100.

In an example embodiment, the first to fourth signal wires SW1 to SW4 may have different lengths from the first to fourth power/ground wires PGW1 to PGW4, respectively. Accordingly, the first to fourth signal wires SW1 to SW4 may overlap each of the first to fourth power/ground wires PGW1 to PGW4 at least in the first direction (e.g., X-direction) to secure a spaced gap between the power/ground wires and the signal wire, and to reduce the risk of a short occurring between adjacent wires, when compared to related semiconductor packages.

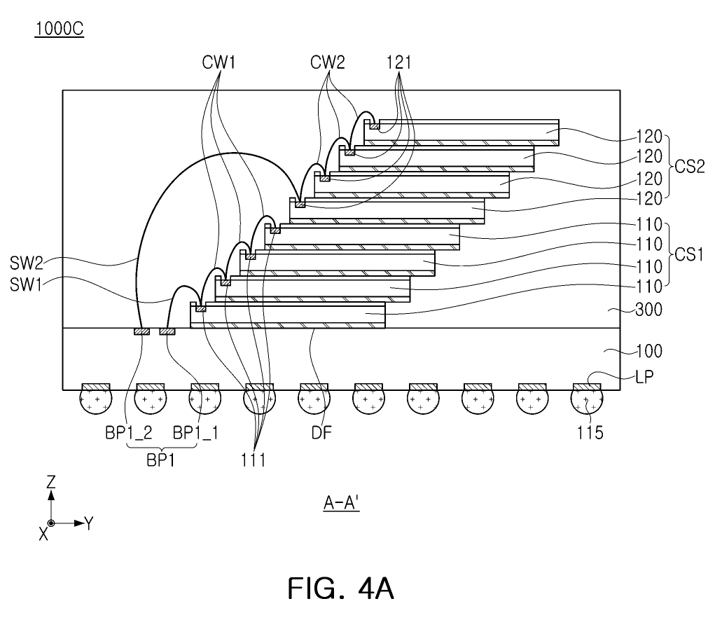

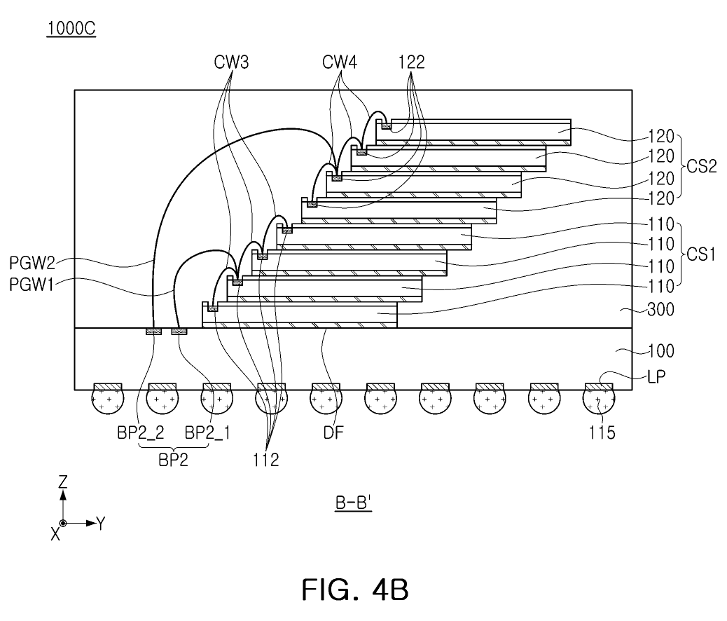

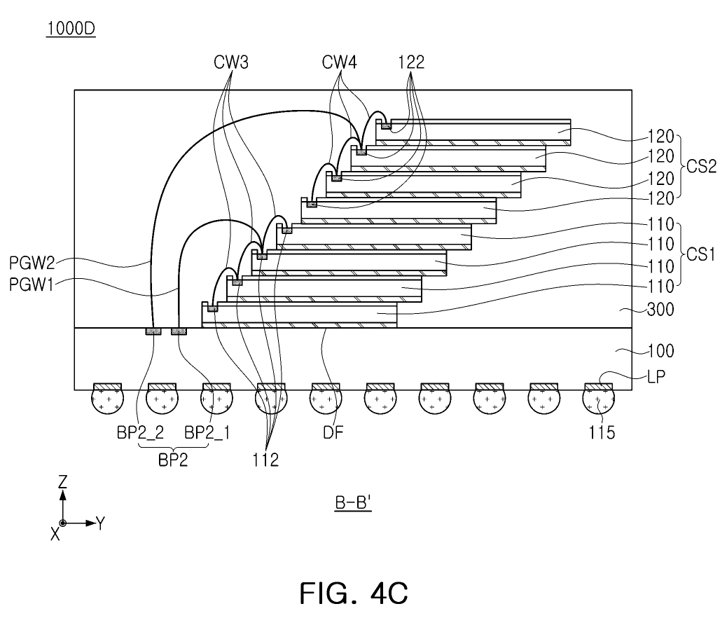

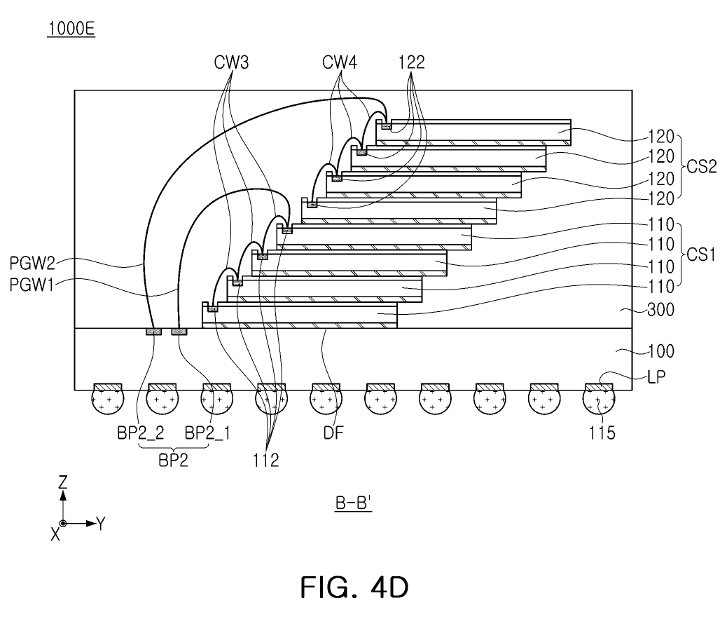

FIG. 4A is a schematic cross-sectional view of a semiconductor package 1000C, according to an example embodiment. FIG. 4A illustrates a cross-section of FIG. 2, taken along the cutting line A–A'. FIG. 4B is a schematic cross-sectional view of a semiconductor package 1000C, according to an example embodiment. FIG. 4B illustrates a cross-section of FIG. 2, taken along the cutting line B–B'. FIG. 4C is a schematic cross-sectional view of a semiconductor package 1000D, according to an example embodiment. FIG. 4C illustrates a cross-section of FIG. 2, taken along line B–B' and illustrates a drawing, corresponding to FIG. 4B. FIG. 4D is a schematic cross-sectional view of a semiconductor package 1000E, according to an example embodiment. FIG. 4D illustrates a cross-section of FIG. 2, taken along the cut line B–B', and illustrates a drawing, corresponding to FIG. 4B.

A semiconductor package 1000C of FIGS. 4A and 4B, a semiconductor package 1000D of FIG. 4C, and a semiconductor package 1000E of FIG. 4D may include and/or may be similar in many respects to the semiconductor package 1000A described above with reference to FIGS. 1, 2, 3A, and 3B, and may include additional features not mentioned above. For example, the semiconductor packages 1000C, 1000D, and 1000E may include two (2) channels. Consequently, repeated descriptions of the semiconductor packages 1000C, 1000D, and 1000E described above with reference to FIGS. 1, 2, 3A, and 3B may be omitted for the sake of brevity.

Referring to FIGS. 4A and 4B, in the semiconductor package 1000C, according to an example embodiment, the substrate 100 may include first and second bonding pads BP1 and BP2 that are arranged alternately in a first direction (e.g., X-direction). The first bonding pads BP1 may include a plurality of first bonding pads BP1_1 and BP1_2 spaced apart from each other in a second direction (e.g., Y-direction), intersecting the first direction (e.g., X-direction). The 1_1 bonding pads BP1_1 may be disposed more adjacently to a first chip stack CS1 than the 1_2 bonding pads BP1_2. The second bonding pads BP2 may include a plurality of second bonding pads BP2_1 and BP2_2 spaced apart from each other in a second direction (e.g., Y-direction), intersecting the first direction (e.g., X- direction). The 2_1 bonding pads BP2_1 may be disposed more adjacently to the first chip stack CS1 than the 2_2 bonding pads BP2_2.

The plurality of semiconductor chips 110 and 120 may form the first and second chip stacks CS1 and CS2. Although FIGS. 4A and 4B illustrate the plurality of semiconductor chips 110 and 120 as having eight (8) semiconductor chips, embodiments of the present disclosure are not limited thereto. For example, the plurality of semiconductor chips 110 and 120 may include fewer chips (e.g., less than eight (8)) or more chips (e.g., greater than eight (8)). In addition, the number of semiconductor chips forming one chip stack (e.g., the first chip stack CS1, or the second chip stack CS2) may be less than or greater than the number of semiconductor chips shown in FIGS. 4A and 4B (e.g., four (4)). For example, the number of semiconductor chips forming one chip stack may be two (2), six (6), nine (9), sixteen (16), or the like. Alternatively or additionally, the number of semiconductor chips in one or more chip stacks of the plurality of chip stacks CS1 and CS2 may be different from the number of semiconductor chips in the remaining chip stacks of the plurality of chip stacks CS1 and CS2.

The plurality of semiconductor chips 110 and 120 may transmit output signals and/or may receive input signals through different channels, respectively. The semiconductor package 1000C, according to the example embodiment, may include two (2) channels as illustrated in FIGS. 4A and 4B. However, embodiments of the present disclosure are not limited thereto.

In an example embodiment, the first connection wires CW1 may electrically connect a plurality of first chips 110 to each other. Accordingly, the first signal pads 111 of the plurality of first chips 110 may be connected to each other via the first connection wires CW1. The second connection wires CW2 may electrically connect the plurality of second chips 120 to each other. Accordingly, the second signal pads 121 of the plurality of second chips 120 may be connected to each other via the second connection wires CW2.

In an example embodiment, the third connection wires CW3 may electrically connect a plurality of first chips 110 to each other. Accordingly, the first power/ground pads 112 of the plurality of first chips 110 may be connected to each other via the third connection wires CW3. The fourth connection wires CW4 may electrically connect the plurality of second chips 120 to each other. Accordingly, second power/ground pads 122 of the plurality of second chips 120 may be connected to each other via the fourth connection wires CW4.

In an example embodiment, the first signal wires SW1 may electrically connect the first signal pads 11 of any one of the plurality of first chips 110 to the 1_1 bonding pads BP1_1 of the substrate 100. For example, the first signal wires SW1 may electrically connect the first signal pads 111 of a lowermost chip of the plurality of first chips 110 to the 1_1 bonding pads BP1_1 of the substrate 100. The second signal wires SW2 may electrically connect the second signal pads 121 any one of the plurality of second chips 120 to the 1_2 bonding pads BP1_2 of the substrate 100. For example, the second signal wires SW2 may electrically connect the second signal pads 121 of a lowermost chip of the plurality of second chips 120 to the 1_2 bonding pads BP1_2 of the substrate 100.

In an example embodiment, the first and second power/ground wires PGW1 and PGW2 may be respectively connected to first and second power/ground pads 112 and 122 of a chip other than the semiconductor chip to which the first and second signal wires SW1 and SW2 are connected.

For example, the first and second power/ground wires PGW1 and PGW2 may be respectively connected to power/ground pads of a semiconductor chip stacked above the chip to which the first and second signal wires SW1 and SW2 are connected.

Referring to FIG. 4B, the first power/ground wires PGW1 may electrically connect the first power/ground pads 112 of a second chip of the plurality of first chips 110 to the 2_1 bonding pads BP2_1 of the substrate 100, and the second power/ground wires PGW2 may electrically connect the second power/ground pads 122 of a second chip of the plurality of second chips 120 to the 2_2 bonding pads BP2_2 of the substrate 100.

Referring to FIG. 4C, the first power/ground wires PGW1 may electrically connect the first power/ground pads 112 of a third chip of the plurality of first chips 110 to the 2_1 bonding pads BP2_1 of the substrate 100, and the second power/ground wires PGW2 may electrically connect the second power/ground pads 122 of a third chip of the plurality of second chips 120 to the 2_2 bonding pads BP2_2 of the substrate 100.

Referring to FIG. 4D, the first power/ground wires PGW1 may electrically connect the first power/ground pads 112 of an uppermost chip of the plurality of first chips 110 to the 2_1 bonding pads BP2_1 of the substrate 100, and the second power ground wires PGW2 may electrically connect the second power/ground pads 122 of an uppermost chip of the plurality of second chips 120 to the 2_2 bonding pads BP2_2 of the substrate 100.

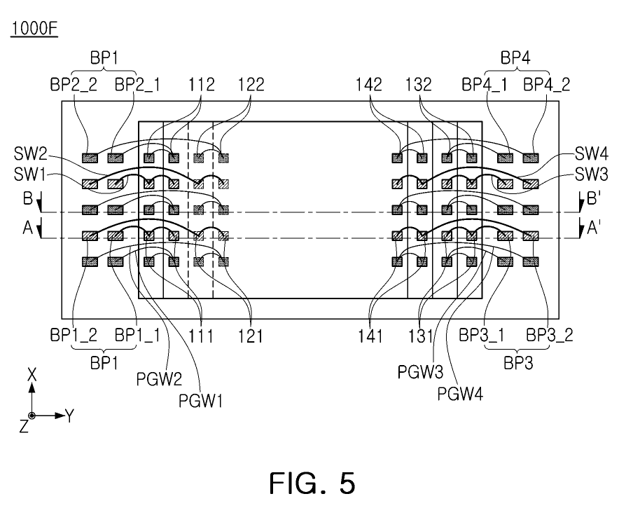

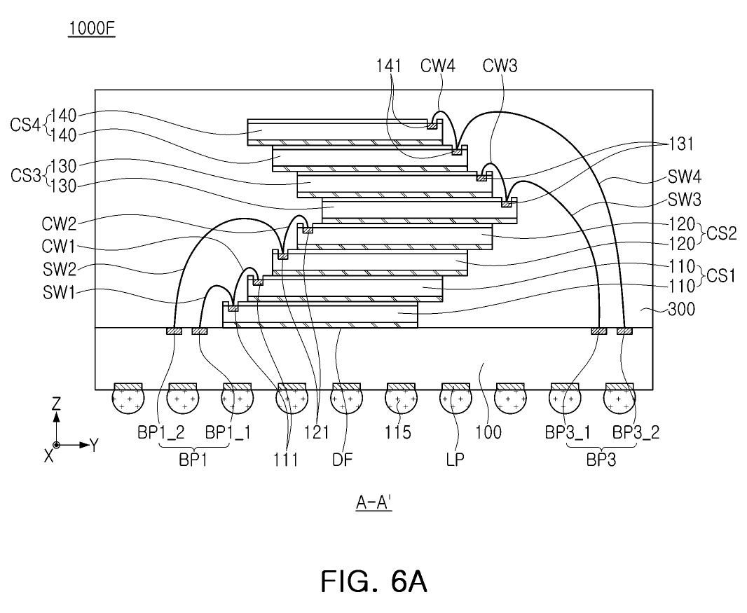

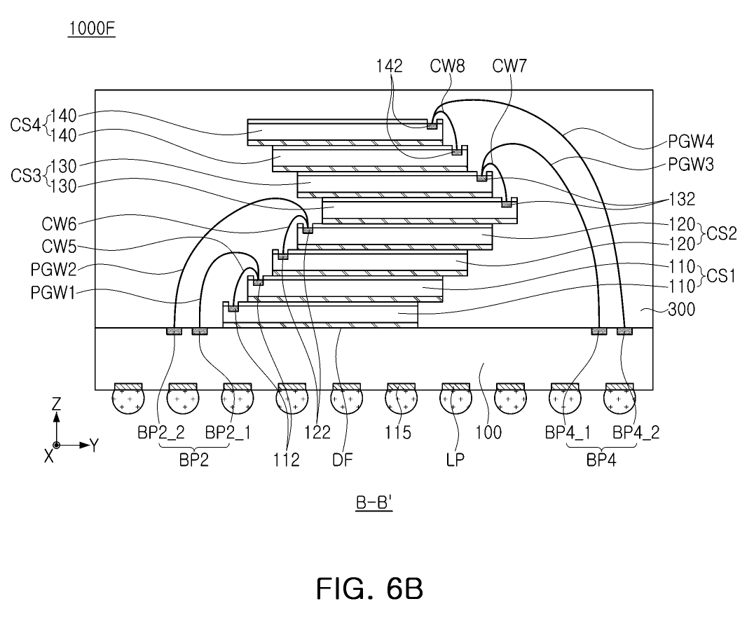

FIG. 5 is a schematic plan view of a semiconductor package 1000F, according to an example embodiment. FIG. 6A is a schematic cross-sectional view of a semiconductor package 1000F, according to an example embodiment. FIG. 6A illustrates a cross-section taken along section line A–A' of FIG. 5. FIG. 6B is a schematic cross-sectional view of a semiconductor package 1000F, according to an example embodiment. FIG. 6B illustrates a cross-section taken along section line B–B' of FIG. 5.

A semiconductor package 1000F of FIGS. 5, 6A, and 6B may include and/or may be similar in many respects to the semiconductor package 1000A described with reference to FIGS. 1, 2, 3A, and 3B, and may include additional features not mentioned above. For example, in the semiconductor package 1000F, a plurality of third chips 130 and a plurality of fourth chips 140 may be offset in a direction opposite to the direction in which the plurality of first chips 110 and the plurality of second chips 120 are offset. Consequently, repeated descriptions of the semiconductor package 1000F described above with reference to FIGS. 1, 2, 3A, and 3B may be omitted for the sake of brevity.

Referring to FIGS. 5, 6A, and 6B, in the semiconductor package 1000F, according to an example embodiment, a substrate 100 may have a first side and a second side opposing each other in a second direction (e.g., Y-direction). The substrate 100 may include the first and second bonding pads BP1 and BP2 arranged alternately in a first direction (e.g., X-direction) in a region adjacent to the first side. The substrate 100 may include third bonding pads BP3 and fourth bonding pads BP4 arranged alternately in the first direction (e.g., X-direction) in a region adjacent to the second side.

The first bonding pads BP1 may include the plurality of first bonding pads BP1_1 and BP1_2 spaced apart from each other in a second direction (e.g., Y-direction) intersecting the first direction (e.g., X-direction). The 1_1 bonding pads BP1_1 may be disposed more adjacently to a first chip stack CS1 than the 1_2 bonding pads BP1_2. The second bonding pads BP2 may include a plurality of second bonding pads BP2_1 and BP2_2 spaced apart from each other in a second direction (e.g., Y-direction) intersecting the first direction (e.g., X-direction). The 2_1 bonding pads BP2_1 may be disposed more adjacently to the first chip stack CS1 than the 2_2 bonding pads BP2_2. The third bonding pads BP3 may include a plurality of third bonding pads BP3_1 and BP3_2 spaced apart from each other in a second direction (e.g., Y-direction) intersecting the first direction (e.g., X-direction). The 3_1 bonding pads BP3_1 may be disposed more adjacently to a third chip stack CS3 than the 3_2 bonding pads BP3_2. The fourth bonding pads BP4 may include a plurality of fourth bonding pads BP4_1 and BP4_2 spaced apart from each other in a second direction (e.g., Y-direction) intersecting the first direction (e.g., X-direction). The 4_1 bonding pads BP4_1 may be disposed more adjacently to the third chip stack CS3 than the 4_2 bonding pads BP4_2.

In a region adjacent to the first side of the substrate 100, the plurality of first chips 110 and the plurality of second chips 120 may be stacked to be offset in one direction (e.g., Y-direction) so that each of the first and second signal pads 111 and 121 and each of the first and second power/ground pads 112 and 122 are exposed in a vertical direction (e.g., Z-direction). In a region adjacent to the second side of the substrate 100, the plurality of third chips 130 and the plurality of fourth chips 140 may be stacked to be offset in a direction opposite to the direction in which the plurality of first chips 110 and the plurality of second chips 120 are offset so that each of the third and fourth signal pads 131 and 141 and each of the third and fourth power/ground pads 132 and 142 are exposed in a vertical direction (e.g., Z-direction).

The first signal wires SW1 may electrically connect the first signal pads 111 of any one of the plurality of first chips 110 to the 1_1 bonding pads BP1_1 of the substrate 100. For example, the first signal wires SW1 may electrically connect the first signal pads 111 of a lowermost chip of the plurality of first chips 110 to the 1_1 bonding pads BP1_1 of the substrate 100. The second signal wires SW2 may electrically connect the second signal pads 121 of any one of the plurality of second chips 120 to the 1_2 bonding pads BP1_2 of the substrate 100. For example, the second signal wires SW2 may electrically connect the second signal pads 121 of a lowermost chip of the plurality of second chips 120 to the 1_2 bonding pads BP1_2 of the substrate 100. The third signal wires SW3 may electrically connect the third signal pads 131 of any one of the plurality of third chips 130 to the 3_1 bonding pads BP3_1 of the substrate 100. For example, the third signal wires SW3 may electrically connect the third signal pads 131 of a lowermost chip of the plurality of third chips 130 to the 3_1 bonding pads BP3_1 of the substrate 100. The fourth signal wires SW4 may electrically connect the fourth signal pads 141 of any one of the plurality of third chips 130 to the 3_2 bonding pads BP3_2 of the substrate 100. For example, the fourth signal wires SW4 may electrically connect the fourth signal pads 141 of a lowermost chip of the plurality of fourth chips 140 to the 3_2 bonding pads BP3_2 of the substrate 100.

In an example embodiment, the first to fourth power/ground wires PGW1 to PGW4 may be respectively connected to first to fourth power/ground pads 112 to 142 of a chip other than the semiconductor chip to which the first to fourth signal wires SW1 to SW4 are connected. For example, the first to fourth power/ground wires PGW1 to PGW4 may be respectively connected to power/ground pads of a semiconductor chip stacked above the chip to which the first to fourth signal wires SW1 to SW4 are connected. The first power/ground wires PGW1 may electrically connect the first power/ground pads 112 of an uppermost chip of the plurality of first chips 110 to the 2_1 bonding pads BP2_1 of the substrate 100. The second power/ground wires PGW2 may electrically connect the second power/ground pads 122 of an uppermost chip of the plurality of second chips 120 to the 2_2 bonding pads BP2_2 of the substrate 100. The third power/ground wires PGW3 may electrically connect the third power/ground pads 132 of an uppermost chip of the plurality of third chips 130 to the 4_1 bonding pads BP4_1 of the substrate 100. The fourth power/ground wires PGW4 may electrically connect the fourth power/ground pads 142 of an uppermost chip of the plurality of fourth chips 140 to the 4_2 bonding pads BP4_2 of the substrate 100.

In an example embodiment, an arrangement state of power/ground wires may vary depending on the number of chip stacks, the number of the plurality of semiconductor chips, the offset arrangement state, or the like. However, embodiments of the present disclosure are not limited thereto.

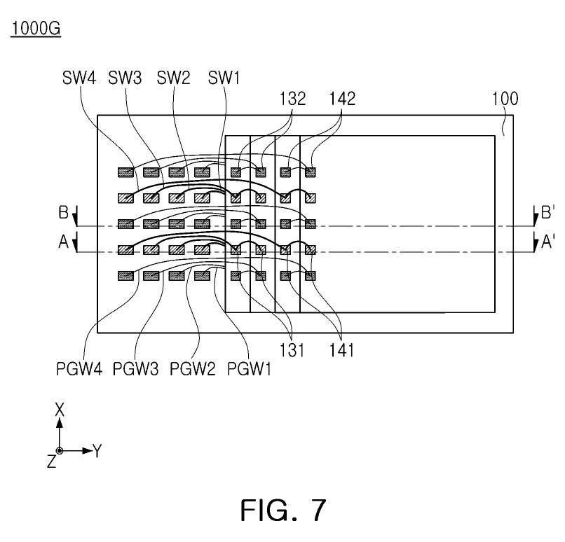

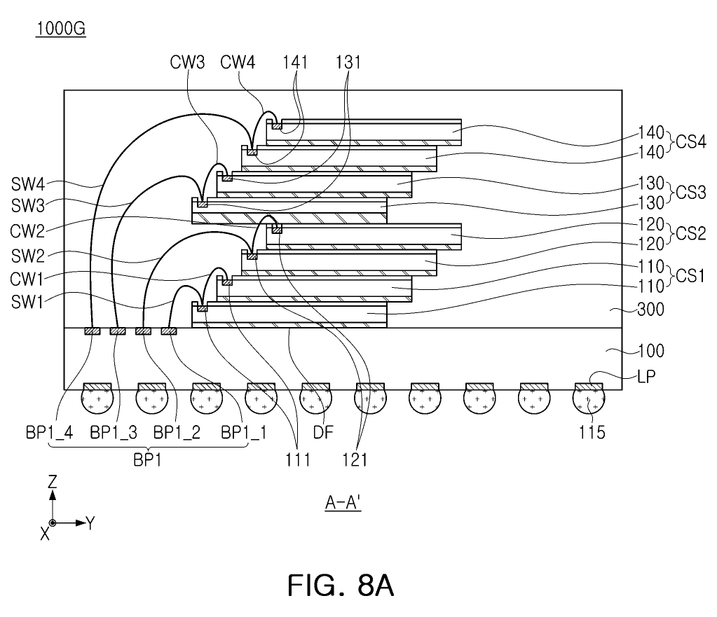

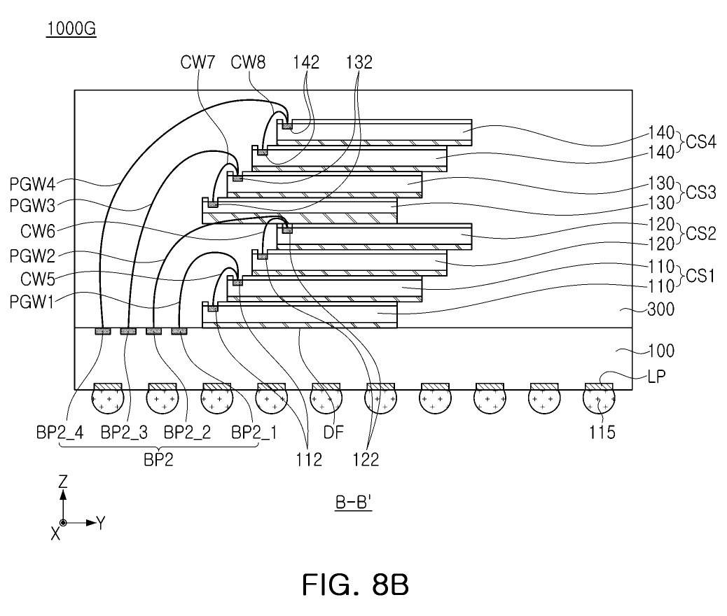

FIG. 7 is a schematic plan view of a semiconductor package 1000G, according to an example embodiment. FIG. 8A is a schematic cross-sectional view of a semiconductor package 1000G, according to an example embodiment. FIG. 8A illustrates a cross-section of FIG. 7, taken along the cutting line A–A'. FIG. 8B is a schematic cross-sectional view of a semiconductor package 1000G, according to an example embodiment. FIG. 8B illustrates a cross-section of FIG. 7, taken along the cutting line B–B'.

A semiconductor package 1000G of FIGS. 7, 8A, and 8B may include and/or may be similar in many respects to the semiconductor package 1000A described above with reference to FIGS. 1, 2, 3A, and 3B, and may include additional features not mentioned above. For example, the semiconductor package 1000G may be offset so that first signal pads 111 of the plurality of first chips 110 and third signal pads 131 of the plurality of third chips 130 overlap in a vertical direction, and second signal pads 121 of the plurality of second chips 120 and fourth signal pads 141 of the plurality of fourth chips 140 overlap in a vertical direction. Consequently, repeated descriptions of the semiconductor package 1000G described above with reference to FIGS. 1, 2, 3A, and 3B may be omitted for the sake of brevity.

Referring to FIGS. 7, 8A, and 8B, in the semiconductor package 1000G, according to an example embodiment, the plurality of first chips 110 and the plurality of second chips 120 may be offset in a second direction (e.g., Y-direction) intersecting the first direction (e.g., X-direction), and the plurality of third chips 130 and the plurality of fourth chips 140 may be offset in the second direction (e.g., Y-direction) on the plurality of second chips 120. Accordingly, the first signal pads 111 of the plurality of first chips 110 and the third signal pads 131 of the plurality of third chips 130 may overlap in a vertical direction (e.g., Z-direction), and the second signal pads 121 of the plurality of second chips 120 and the fourth signal pads 141 of the plurality of fourth chips 140 may overlap in a vertical direction (e.g., in the Z-direction).

In an example embodiment, an arrangement state of the power/ground wires may vary depending on the number of channels, the number of chip stacks, the number of the plurality of semiconductor chips, the offset arrangement state, or the like, and an example embodiment thereof is not limited thereto.

For example, an arrangement state of the signal wires may be similar to or the same as the arrangement state of the signal wires of FIG. 3A, and an arrangement state of the power/ground wires may be similar to or the same as the arrangement state of the power/ground wires of FIG. 3C. However, embodiments of the present disclosure are not limited thereto.

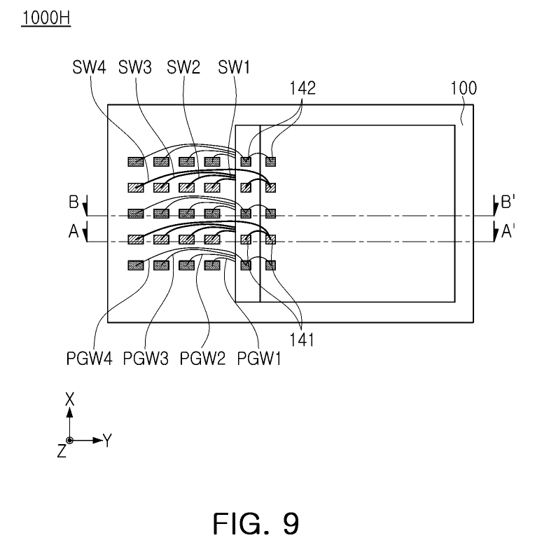

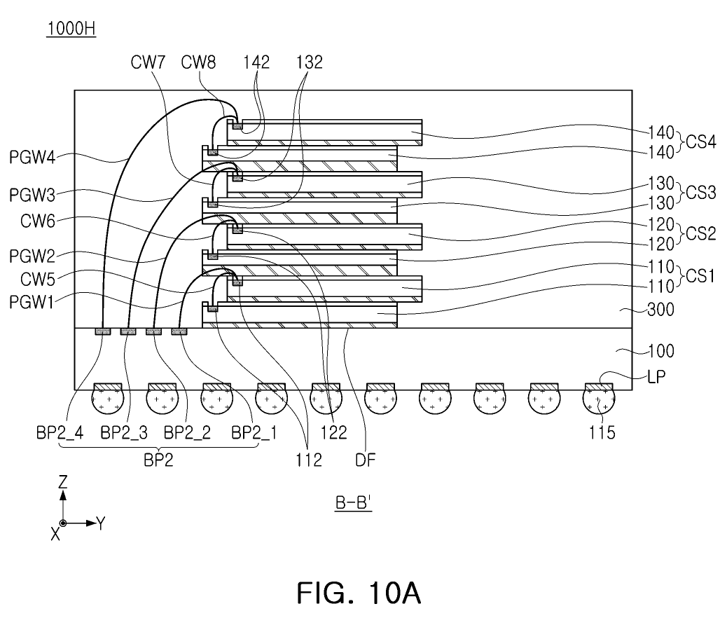

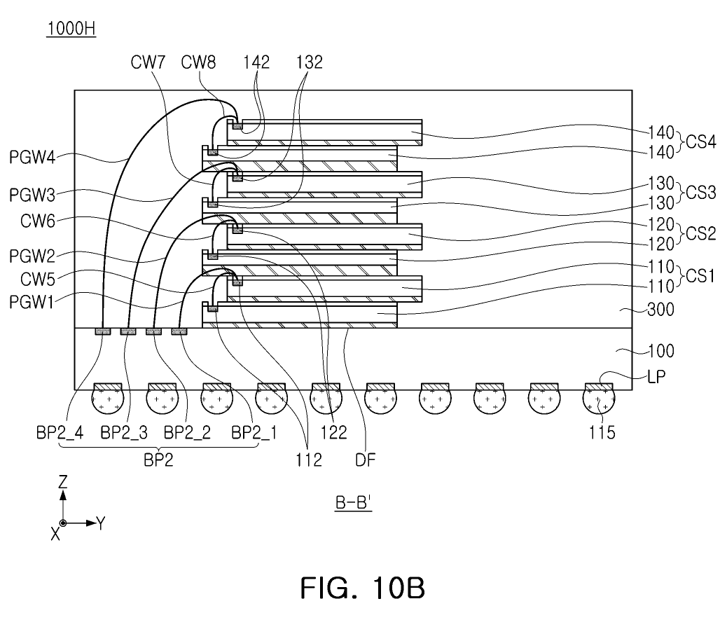

FIG. 9 is a schematic plan view of a semiconductor package 1000H, according to an example embodiment. FIG. 10A is a schematic cross-sectional view of a semiconductor package 1000H, according to an example embodiment. FIG. 10A illustrates a cross-section taken along the cutting line A–A' of FIG. 9. FIG. 10B is a schematic cross-sectional view of a semiconductor package 1000H, according to an example embodiment. FIG. 10B illustrates a cross-section taken along the cutting line B–B' of FIG. 9.

A semiconductor package 1000H of FIGS. 9, 10A, and 10B may include and/or may be similar in many respects to the semiconductor package 1000A described above with reference to FIGS. 1, 2, 3A, and 3B, and may include additional features not mentioned above. For example, the first signal pads 111 of the plurality of first chips 110, the second signal pads 121 of the plurality of second chips 120, the third signal pads 131 of the plurality of third chips 130, and the fourth signal pads 141 of the plurality of fourth chips 140 may be offset to overlap in a vertical direction. Consequently, repeated descriptions of the semiconductor package 1000H described above with reference to FIGS. 1, 2, 3A, and 3B may be omitted for the sake of brevity.

Referring to FIGS. 9, 10A, and 10B, in the semiconductor package 1000H, according to an example embodiment, the plurality of first chips 110 may be offset in a second direction (e.g., a Y-direction), the plurality of second chips 120 may be offset in the second direction (e.g., the Y-direction) on the plurality of first chips 110, the plurality of third chips 130 may be offset in the second direction (e.g., the Y-direction) on the plurality of second chips 120, and the plurality of fourth chips 140 may be offset in the second direction (e.g., the Y-direction) on the plurality of third chips 130. The first signal pads 111 of the plurality of first chips 110, the second signal pads 121 of the plurality of second chips 120, the third signal pads 131 of the plurality of third chips 130, and the fourth signal pads 141 of the plurality of fourth chips 140 may be offset so as to overlap in a vertical direction (e.g., in a Z-direction).

In an example embodiment, an arrangement form of the power/ground wires may vary depending on the number of channels, the number of chip stacks, the number of multiple semiconductor chips, the offset arrangement, or the like. However, embodiments of the present disclosure are not limited thereto.

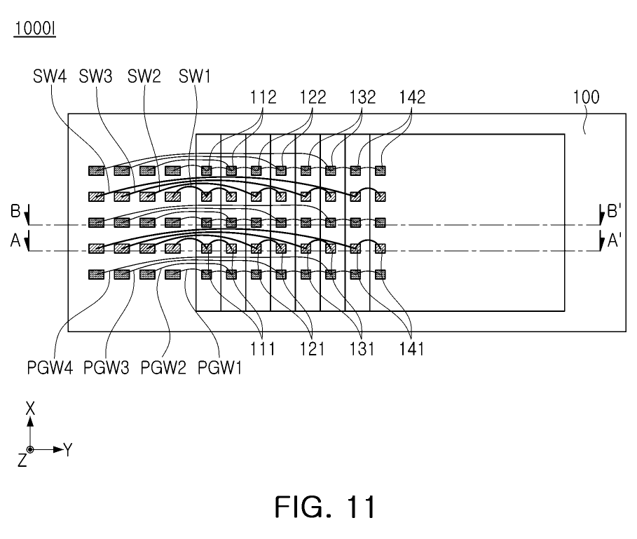

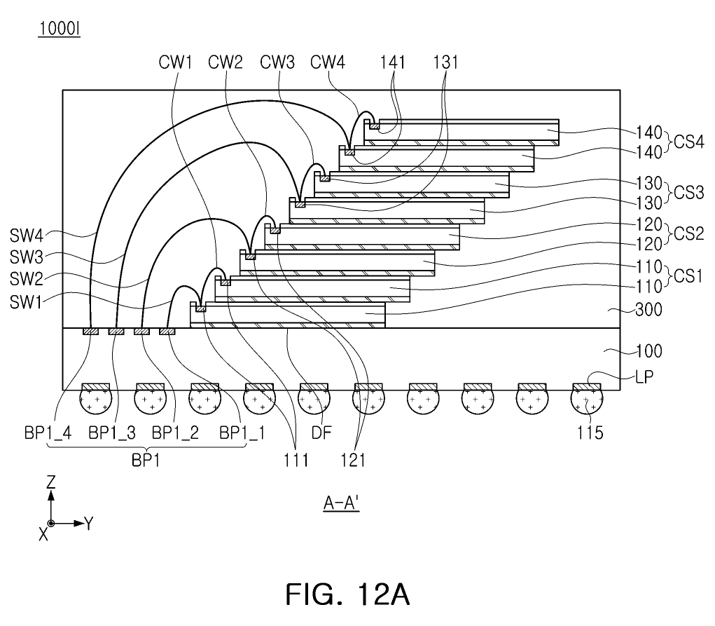

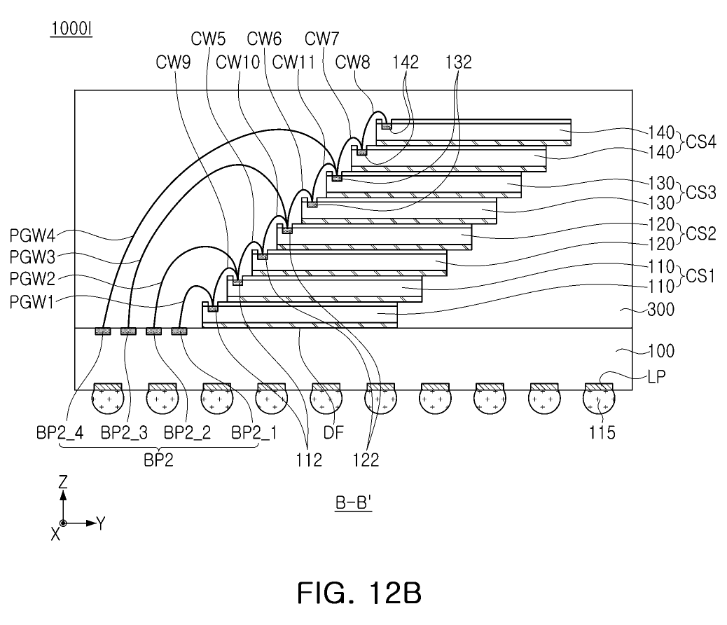

FIG. 11 is a schematic plan view of a semiconductor package 1000I, according to an example embodiment. FIG. 12A is a schematic cross-sectional view of a semiconductor package 1000I, according to an example embodiment. FIG. 12A illustrates a cross-section taken along the cutting line A–A' of FIG. 11. FIG. 12B is a schematic cross-section of a semiconductor package 1000I according to an example embodiment. FIG. 12B illustrates a cross-section taken along the cutting line B–B' of FIG. 11.

A semiconductor package 1000I of FIGS. 11, 12A and 12B may include and/or may be similar in many respects to the semiconductor package 1000A described above with reference to FIGS. 1, 2, 3A, and 3B, and may include additional features not mentioned above. For example, the power/ground pads of a plurality of semiconductor chips 110 to 140 may be connected through connection wires.

Referring to FIGS. 11, 12A and 12B, the semiconductor package 1000I, according to an example embodiment, may further include ninth connection wires CW9, tenth connection wires CW10, and eleventh connection wires CW11. The ninth connection wires CW9 may electrically connect the plurality of first chips 110 to each other. Accordingly, the first power/ground pads 112 of the plurality of first chips 110 may be connected to each other through the ninth connection wires CW9. The tenth connection wires CW10 may electrically connect the plurality of second chips 120 to each other. Accordingly, the first power/ground pads 112 of the plurality of first chips 110 may be connected to each other through the ninth connection wires CW9. The tenth connection wires CW10 may electrically connect the plurality of second chips 120 to each other.

The number of additional connection wires may vary depending on an arrangement state of the power/ground wires. For example, in the semiconductor package 1000B of FIG. 3C, connection wires electrically connecting the plurality of semiconductor chips 110 to 140 to each other may be further included.

In an example embodiment, the arrangement state of power/ground wires may vary depending on the number of channels, the number of chip stacks, the number of the plurality of semiconductor chips, the offset arrangement state, or the like. However, embodiments of the present disclosure are not limited thereto.

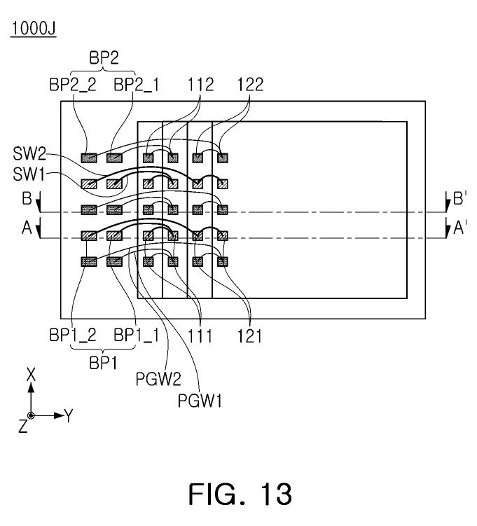

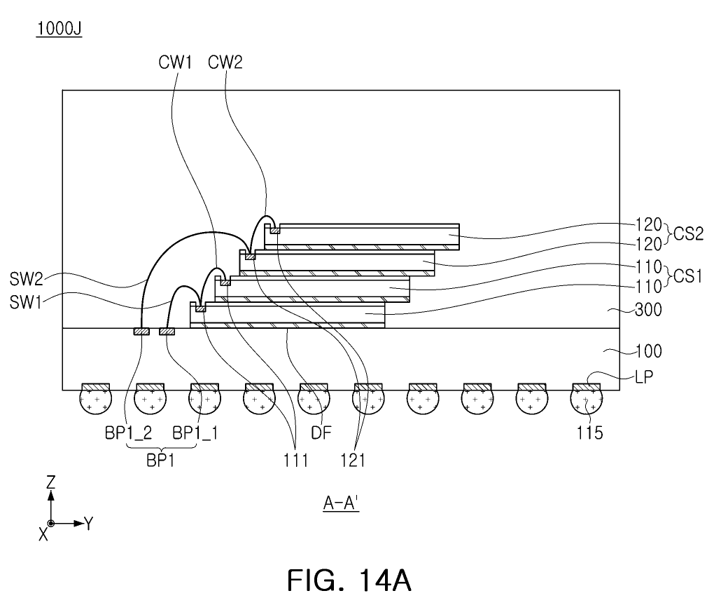

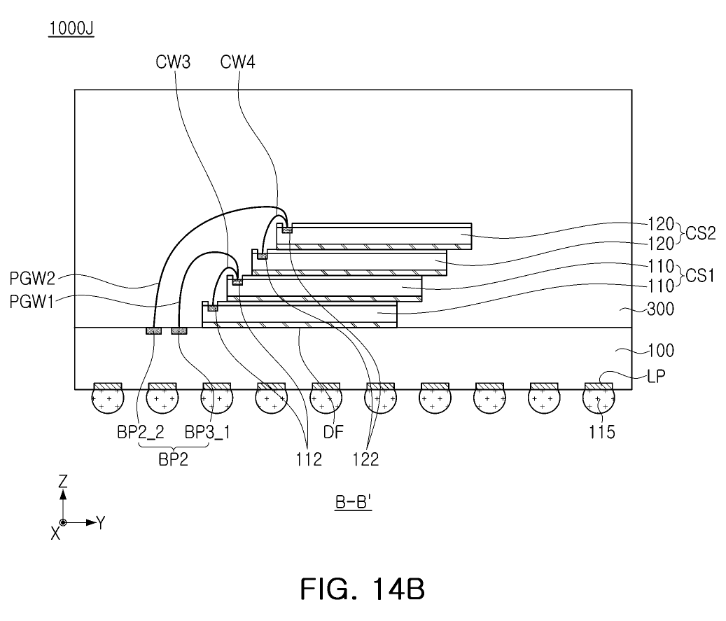

FIG. 13 is a schematic plan view of a semiconductor package 1000J according to an example embodiment. FIG. 14A is a schematic cross-sectional view of a semiconductor package 1000J according to an example embodiment. FIG. 14A illustrates a cross-section taken along the cutting line A–A' of FIG. 13. FIG. 14B is a schematic cross-section of a semiconductor package 1000J according to an example embodiment. FIG. 14B illustrates a cross-section taken along the cutting line B–B' of FIG. 13.

A semiconductor package 1000J of FIGS. 13, 14A, and 14B may include and/or may be similar in many respects to the semiconductor package 1000C described above with reference to FIGS. 4A and 4B, and may include additional features not mentioned above. For example, the semiconductor package 1000J may include two (2) channels and the chip stacks may be formed by two (2) semiconductor chips.

Referring to FIGS. 13, 14A, and 14B, in an example embodiment, the first signal wires SW1 may electrically connect first signal pads of any one of the plurality of first chips 110 to 1_1 bonding pads BP1_1 of a substrate 100. For example, the first signal wires SW1 may electrically connect the first signal pads 111 of the lowermost chip of the plurality of first chips 110 to the first_1 bonding pads BP1_1 of the substrate 100.

The second signal wires SW2 may electrically connect second signal pads of any one of the plurality of second chips 120 to 1_2 bonding pads BP1_2 of the substrate 100. For example, the second signal wires SW2 may electrically connect the second signal pads 121 of the lowermost chip of the plurality of second chips 120 to the 1_2 bonding pads BP1_2 of the substrate 100.

In an example embodiment, the first and second power/ground wires PGW1 and PGW2 may be respectively connected to the first and second power/ground pads 112 and 122 of a chip other than a semiconductor chip to which the first and second signal wires SW1 and SW2 are connected.

For example, the first and second power/ground wires PGW1 and PGW2 may be respectively connected to power/ground pads of a semiconductor chip stacked above the chip to which the first and second signal wires SW1 and SW2 are connected. The first power/ground wires PGW1 may electrically connect the first power/ground pads 112 of the uppermost chip of the plurality of first chips 110 to the 2_1 bonding pads BP2_1 of the substrate 100. The second power/ground wires PGW2 may electrically connect the second power/ground pads 122 of the uppermost chip of the plurality of second chips 120 to the 2_2 bonding pads BP2_2 of the substrate 100.

In an example embodiment, the arrangement state of power/ground wires may vary depending on the number of channels, the number of chip stacks, the number of a plurality of semiconductor chips, the arrangement state of offset, or the like. However, embodiments of the present disclosure are not limited thereto.

According to example embodiments of the present disclosure, by connecting power/ground wires to a chip other than a chip to which signal wires are connected, a short between the signal wires and the power/ground wires may be prevented, and a semiconductor package having improved reliability, when compared to related semiconductor packages, may be provided.

According to example embodiments of the present disclosure, a semiconductor package reducing a return path and improving signal integrity characteristics may be provided, by alternately arranging signal pads and power/ground pads in a chip stack, and connecting long wires to the power/ground pads.

The various advantageous and beneficial advantages and effects of the present disclosure are not limited to the above-described contents, and may be more easily understood in the course of explaining specific embodiments of the present disclosure.

According to an aspect of the present disclosure, provided is a method for manufacturing a semiconductor package, the method includes forming first bonding pads and second bonding pads on a substrate, stacking a plurality of semiconductor chips including signal pads and power/ground pads on the substrate, forming bonding wires electrically coupling the plurality of semiconductor chips with the first bonding pads and the second bonding pads, and forming an encapsulant at least partially covering the plurality of semiconductor chips on the substrate. The bonding wires include a first bonding wire coupling the first bonding pads with at least a portion of the signal pads of the plurality of semiconductor chips and a second bonding wire coupling the second bonding pads with at least a portion of the power/ground pads of the plurality of semiconductor chips. A chip to which the second bonding wire is coupled is stacked above or below a chip to which the first bonding wire is coupled.

While example embodiments have been illustrated and described above, it is to be apparent to those skilled in the art that modifications and variations may be made without departing from the scope of the present disclosure as defined by the appended claims.

What is claimed is:

1. A semiconductor package, comprising:
a substrate comprising first bonding pads and second bonding pads, the first bonding pads and the second bonding pads being disposed in a first direction;
a first chip stack on the substrate, the first chip stack comprising a plurality of first chips stacked vertically, the plurality of first chips comprising first signal pads and first power/ground pads, the first signal pads and the first power/ground pads being disposed in the first direction;
a second chip stack on the first chip stack, the second chip stack comprising a plurality of second chips stacked vertically, the plurality of second chips comprising second signal pads and second power/ground pads, the second signal pads and the second power/ground pads being disposed in the first direction;
a third chip stack on the second chip stack, the third chip stack comprising a plurality of third chips stacked vertically, the plurality of third chips comprising third signal pads and third power/ground pads, the third signal pads and the third power/ground pads being disposed in the first direction;
a fourth chip stack on the third chip stack, the fourth chip stack comprising a plurality of fourth chips stacked vertically, the plurality of fourth chips comprising fourth signal pads and fourth power/ground pads, the fourth signal pads and the fourth power/ground pads being disposed in the first direction;
first signal wires coupling one or more of the first signal pads of a first chip of the plurality of first chips and the first bonding pads;
second signal wires coupling one or more of the second signal pads of a first chip of the plurality of second chips and the first bonding pads;
third signal wires coupling one or more of the third signal pads of a first chip of the plurality of third chips and the first bonding pads;
fourth signal wires coupling the fourth signal pads of a first chip of the plurality of fourth chips and the first bonding pads;
first power/ground wires coupling the first power/ground pads of a second chip of the plurality of first chips and the second bonding pads, the second chip of the plurality of first chips being different from the first chip of the plurality of first chips;
second power/ground wires coupling the second power/ground pads of a second chip of the plurality of second chips and the second bonding pads, the second chip of the plurality of second chips being different from the first chip of the plurality of second chips; and
third power/ground wires coupling the third power/ground pads of a second chip of the plurality of third chips and the second bonding pads, the second chip of the plurality of third chips being different from the first chip of the plurality of third chips.

2. The semiconductor package of claim 1, wherein the fourth power/ground pads of a lowermost chip of the plurality of fourth chips are coupled with the third power/ground pads of an uppermost chip of plurality of third chips by connection wires.

3. The semiconductor package of claim 1, wherein lengths of the fourth signal wires are different from lengths of the third power/ground wires.

4. The semiconductor package of claim 1, wherein lengths of the third signal wires are different from lengths of the second power/ground wires.

5. The semiconductor package of claim 1, wherein lengths of the second signal wires are different from lengths of the first power/ground wires.

6. The semiconductor package of claim 1, further comprising:
fourth power/ground wires coupling the fourth power/ground pads of a second chip of the plurality of fourth chips and the second bonding pads, the second chip of the plurality of fourth chips being different from the first chip of the plurality of fourth chips.

7. The semiconductor package of claim 6, wherein each of the first signal wires, the second signal wires, the third signal wires, and the fourth signal wires has a different length from each of the first power/ground wires, the second power/ground wires, the third power/ground wires, and the fourth power/ground wires.

8. The semiconductor package of claim 1, wherein the first signal wires are coupled with the first signal pads of a lowermost chip of the plurality of first chips,
wherein the second signal wires are coupled with the second signal pads of a lowermost chip of the plurality of second chips,
wherein the third signal wires are coupled with the third signal pads of a lowermost chip of the plurality of third chips, and
wherein the fourth signal wires are coupled with the fourth signal pads of a lowermost chip of the plurality of fourth chips.

9. The semiconductor package of claim 1, wherein the first power/ground pads of the plurality of first chips are coupled with the second power/ground pads of the plurality of second chips by connection wires.

10. The semiconductor package of claim 1, wherein the second power/ground pads of the plurality of second chips are coupled with the third power/ground pads of the plurality of third chips by connection wires.

11. The semiconductor package of claim 1, wherein the plurality of first chips, the plurality of second chips, the plurality of third chips, and the plurality of fourth chips are offset from each other in a second direction, the second direction intersecting the first direction, and
wherein the first signal pads, the second signal pads, the third signal pads, the fourth signal pads, the first power/ground pads, the second power/ground pads, the third power/ground pads, and the fourth power/ground pads are exposed in a vertical direction.

12. The semiconductor package of claim 1, wherein the substrate comprises a first side and a second side opposite to the first side in a second direction, the second direction intersecting the first direction,
wherein the plurality of first chips and the plurality of second chips are offset from each other in a first horizontal direction,
wherein the first signal pads, the second signal pads, the first power/ground pads, and the second power/ground pads are exposed in a vertical direction in a first region adjacent to the first side,
wherein the plurality of third chips and the plurality of fourth chips are offset from each other in a second horizontal direction, the second horizontal direction being opposite to the first horizontal direction, and
wherein the third signal pads, the fourth signal pads, the third power/ground pads, and the fourth power/ground pads are exposed in the vertical direction in a second region adjacent to the second side.

13. The semiconductor package of claim 1, wherein the plurality of first chips, the plurality of second chips, the plurality of third chips, and the plurality of fourth chips are offset from each other in a second direction, the second direction intersecting the first direction,
wherein the first signal pads and the third signal pads at least partially overlap in a vertical direction, and
wherein the second signal pads and the fourth signal pads at least partially overlap in the vertical direction.

14. The semiconductor package of claim 1, wherein the plurality of first chips, the plurality of second chips, the plurality of third chips, and the plurality of fourth chips are offset from each other in a second direction, the second direction intersecting the first direction, and
wherein the first signal pads, the second signal pads, the third signal pads, and the fourth signal pads at least partially overlap in a vertical direction.

15. A semiconductor package, comprising:
a substrate comprising first bonding pads and second bonding pads, the first bonding pads and the second bonding pads being disposed in a first direction;
a first chip stack comprising a plurality of first chips stacked on the substrate, wherein each of the plurality of first chips comprises first signal pads and first power/ground pads, the first signal pads and the first power/ground pads being disposed in the first direction;
a second chip stack comprising a plurality of second chips stacked on the first chip stack, wherein each of the plurality of second chips comprises second signal pads and second power/ground pads, the second signal pads and the second power/ground pads being disposed in the first direction;
first signal wires coupling one or more of the first signal pads of a first chip of the plurality of first chips and the first bonding pads;
second signal wires coupling one or more of the second signal pads of a first chip of the plurality of second chips and the second bonding pads; and
first power/ground wires coupling one or more first power/ground pads of a second chip of the plurality of first chips and the second bonding pads,
wherein the one or more first power/ground pads of the second chip are coupled with one or more of the second power/ground pads by first connection wires,
wherein the first signal pads of each of the plurality of first chips are coupled with the first signal wires by second connection wires, and
wherein the second signal pads of each of the plurality of second chips are coupled with the second signal wires by third connection wires.

16. The semiconductor package of claim 15, wherein the one or more of the first signal pads of the first chip to which the first signal wires are coupled and the one or more first power/ground pads of the second chip are respectively disposed on the plurality of first chips, and
wherein the first chip of the plurality of first chips is different from the second chip of the plurality of first chips.

17. The semiconductor package of claim 15, wherein the first signal pads and the second signal pads are electrically isolated from each other.

18. The semiconductor package of claim 15, wherein the one or more first power/ground pads of the second chip and remaining first power/ground pads of remaining chips of the plurality of first chips stacked below the second chip are electrically isolated from each other.

19. A semiconductor package, comprising:
a substrate comprising first bonding pads and second bonding pads;
a plurality of semiconductor chips stacked on the substrate, each semiconductor chip of the plurality of semiconductor chips comprising signal pads and power/ground pads; and
bonding wires coupling the first bonding pads and the second bonding pads to the plurality of semiconductor chips,
wherein the bonding wires comprise:
a first bonding wire coupling the first bonding pads to at least a portion of the signal pads of the plurality of semiconductor chips; and
a second bonding wire coupling the second bonding pads to at least a portion of the power/ground pads of the plurality of semiconductor chips, and
wherein a second chip of the plurality of semiconductor chips to which the second bonding wire is coupled is stacked above or below a first chip of the plurality of semiconductor chips to which the first bonding wire is coupled.

20. The semiconductor package of claim 19, wherein the second chip to which the second bonding wire is coupled is adjacent to the first chip to which the first bonding wire is coupled.
